(19) United States
(12) Patent Application Publication
(10) Pub. No.: US 2022/0208985 A1
(43) Pub. Date: Jun. 30, 2022

(54) SEMICONDUCTOR DEVICE AND METHOD FOR FABRICATING THE SAME

(71) Applicant: SK hynix Inc., Gyeonggi-do (KR)

(72) Inventor: Young Gwang YOON, Gyeonggi-do (KR)

(21) Appl. No.: 17/465,588

(22) Filed: Sep. 2, 2021

(30) Foreign Application Priority Data
Dec. 28, 2020 (KR) 10-2020-0184851

(51) Int. Cl. H01L 29/51; H01L 27/088; H01L 21/8238

(52) U.S. Cl. CPC H01L 29/511; H01L 21/823857; H01L 27/0883

(57) ABSTRACT

A semiconductor device includes a substrate including a first NMOS region and a second NMOS region, a first transistor including a first shifter layer disposed in the first NMOS region, and a second transistor including a second shifter layer disposed in the second NMOS region, wherein each of the first shifter layer and the second shifter layer includes first dipole inducing species and the second shifter layer further includes second dipole inducing species.

### CROSS-REFERENCE TO RELATED APPLICATIONS

The present application claims priority to Korean Patent Application No. 10-2020-0184851, filed on Dec. 28, 2020, which is incorporated herein by reference in its entirety.

### TECHNICAL FIELD

This patent document relates to a semiconductor device and methods for fabricating the same and, more particularly, to a semiconductor device including a high-k dielectric layer and methods for fabricating the same.

### BACKGROUND

Recently, as integration of semiconductor devices increases, a leakage current also increases through a gate insulation layer of the transistors employed in the semiconductor devices. Thus, to alleviate this issue, a gate insulation layer may be formed of a high-k dielectric material.

### SUMMARY

Various embodiments of the present invention are directed to a semiconductor device and methods for fabricating the same that improve the reliability of a high-k dielectric layer employed therein.

In accordance with an embodiment, a semiconductor device includes a substrate including a first NMOS region and a second NMOS region, a first transistor including a first shifter layer disposed in the first NMOS region, and a second transistor including a second shifter layer disposed in the second NMOS region, wherein each of the first shifter layer and the second shifter layer includes first dipole inducing species and the second shifter layer further includes second dipole inducing species.

In accordance with another embodiment of the present invention, a semiconductor device includes a substrate including a first PMOS region and a second PMOS region, a first transistor including a first shifter layer disposed in the first PMOS region, and a second transistor including a second shifter layer disposed in the second PMOS region, wherein the first shifter layer includes a P-type dipole inducing material and the second shifter layer includes a combination of a P-type dipole inducing material and an N-type dipole inducing material.

In accordance with yet another embodiment of the present invention, a method for fabricating a semiconductor device includes sequentially stacking an interface layer and a high-k dielectric layer on a substrate, in which a NMOS region and a PMOS region are defined, forming a first N-type shifter layer over the high-k dielectric layer in the NMOS region, forming a first P-type shifter layer over the high-k dielectric layer in the PMOS region, forming a second N-type shifter layer over the first N-type shifter layer and the first P-type shifter layer, forming a second P-type shifter layer over the second N-type shifter layer, sequentially patterning the second P-type shifter layer, the second N-type shifter layer, and the first N-type shifter layer to form a plurality of N-type shifter structures over the NMOS region of the substrate, and sequentially patterning the second P-type shifter layer, the second N-type shifter layer, and the first P-type shifter layer to form a plurality of P-type shifter structures over the PMOS region of the substrate.

In accordance with yet another embodiment of the present invention, a semiconductor device includes a substrate including first and second transistor region; a first gate stack formed over the first transistor region, the first gate stack including first dipole inducing species; and a second gate stack formed over the second transistor region, the second gate stack including a second dipole inducing species, wherein the first dipole inducing species have a higher concentration than the second dipole inducing species, and wherein the first dipole inducing species and the second dipole inducing species comprise the same material. The first and second dipole inducing species may include lanthanum or aluminum. The first and second transistor region may include NMOSFET or PMOSFET.

Various embodiments of the present invention are directed to methods for fabricating a semiconductor device through a series of processes that sequentially remove shifter layers. Thus, the embodiments of the present invention can fundamentally prevent direct or indirect damages, caused by a cleaning or an ashing process, on dipole interfaces or high-k dielectric layers.

The embodiments of the present invention can improve the reliability of transistors having different threshold voltages.

### BRIEF DESCRIPTION OF THE DRAWINGS

FIG. 1 is a diagram illustrating a semiconductor device according to an embodiment of the present disclosure.

FIGS. 2A to 2I are diagrams illustrating a method for fabricating a semiconductor device according to an embodiment of the present disclosure.

FIG. 3 is a diagram illustrating a semiconductor device according to an embodiment of the present disclosure.

FIGS. 4A to 4I are diagrams illustrating another method for fabricating a semiconductor device according to an embodiment of the present disclosure.

FIGS. 5A to 5J are diagrams illustrating another method for fabricating a semiconductor device according to an embodiment of the present disclosure.

FIG. 6 is a diagram illustrating a semiconductor device according to an embodiment of the present disclosure.

FIGS. 7A to 7C are diagrams illustrating another method for fabricating a semiconductor device according to an embodiment of the present disclosure

### DETAILED DESCRIPTION

Various embodiments described herein will be described with reference to cross-sectional views, plane views and block diagrams, which are example schematic views of the present invention. Thus, the structures of the drawings may be modified by fabricating techniques and/or tolerances. The embodiments of the present invention are not limited to the specific structures shown in the drawings, but include any changes in the structures that may be produced according to the fabricating process. Also, any regions and shapes of regions illustrated in the drawings are intended to illustrate specific examples of structures of regions of the various elements, and are not intended to limit the scope of the invention.

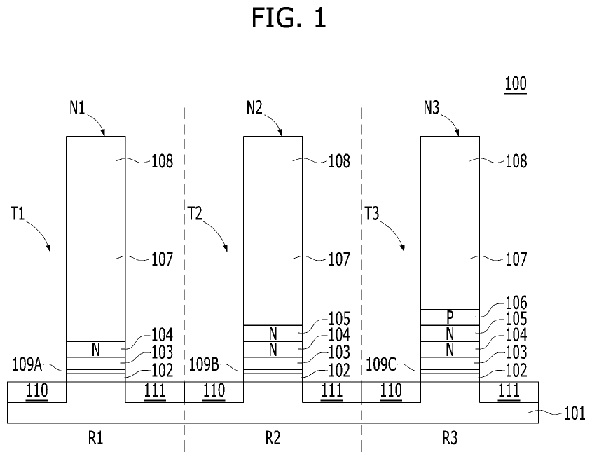

FIG. 1 is a diagram illustrating a semiconductor device according to an embodiment of the present disclosure.

Referring to FIG. 1, a semiconductor device 100 may include a first transistor T1, a second transistor T2, and a third transistor T3. The first transistor T1 may be formed over a first region R1, the second transistor T2 may be formed over a second region R2, and the third transistor T3 may be formed over a third region R3. Each of the first to third transistors T1 to T3 may be NMOSFET. Although not illustrated, the first to third transistors T1 to T3 may be divided by an isolation layer as is well-known in the art. In this regard, it is noted that well known features may be omitted for avoiding obfuscating the description with unnecessary details of well-known features.

The first transistor T1 may include a first gate stack N1 formed over a substrate 101 in the first region R1. The first transistor T1 may include a first source region 110 and a first drain region 111 formed on both sides of the first gate stack N1 over the substrate 101. The first gate stack N1 may be formed to include an interface layer 102, a high-k dielectric layer 103, a first N-type shifter layer 104, a gate electrode 107, and a gate capping layer 108 which are sequentially stacked in the recited order. The first gate stack Ni may further include a first dipole interface 109A formed between the interface layer 102 and the high-k dielectric layer 103. The first dipole interface 109A may include dipole inducing chemical species for controlling a threshold voltage of the first transistor T1. As will be illustrated below, the first dipole interface 109A may be formed between the interface layer 102 and the high-k dielectric layer 103 through diffusion of dipole inducing chemical species from the first N-type shifter layer 104. The threshold voltage of the first transistor T1 is controlled by the first dipole interface 109A. In an embodiment, the first dipole interface 109A may include lanthanides. The first dipole interface 109A may include, for example, lanthanum (La).

The second transistor T2 may include a second gate stack N2 formed over the substrate 101 in the second region R2. The second transistor T2 may include the first source region 110 and the first drain region 111 formed on both sides of the second gate stack N2 over the substrate 101. The second gate stack N2 may be formed to include the interface layer 102, the high-k dielectric layer 103, the first N-type shifter layer 104, a second N-type shifter layer 105, the gate electrode 107, and the gate capping layer 108 which are sequentially stacked in the recited order. The second gate stack N2 may further include a second dipole interface 109B formed between the interface layer 102 and the high-k dielectric layer 103. The second dipole interface 109B may include dipole inducing chemical species for controlling a threshold voltage of the second transistor T2. As will be illustrated below, the second dipole interface 109B may be formed between the interface layer 102 and the high-k dielectric layer 103 through diffusion of dipole inducing chemical species from the first and second N-type shifter layers 104 and 105 containing dipole inducing chemical species. The threshold voltage of the second transistor T2 is controlled by the second dipole interface 109B. In an embodiment, the second dipole interface 109B may include lanthanides. The second dipole interface 109B may include, for example, lanthanum (La).

The third transistor T3 may include a third gate stack N3 formed over the substrate 101 in the third region R3. The third transistor T3 may include the first source region 110 and the first drain region 111 formed on both sides of the third gate stack N3 over the substrate 101. The third gate stack N3 may be formed to include the interface layer 102, the high-k dielectric layer 103, the first and second N-type shifter layers 104 and 105, a P-type shifter layer 106, the gate electrode 107, and the gate capping layer 108 which are sequentially stacked in the recited order. The third gate stack N3 may further include a third dipole interface 109C formed between the interface layer 102 and the high-k dielectric layer 103. The third dipole interface 109C may include dipole inducing chemical species for controlling a threshold voltage of the third transistor T3. As will be illustrated below, the third dipole interface 109C may be formed between the interface layer 102 and the high-k dielectric layer 103 through diffusion of dipole inducing chemical species from the first and second N-type shifter layers 104 and 105 containing dipole inducing chemical species. The threshold voltage of the third transistor T3 is controlled by the third dipole interface 109C. The third dipole interface 109C may include lanthanides. The third dipole interface 109C may include, for example, lanthanum (La).

In accordance with FIG. 1, the first to third transistors T1 to T3 may have different threshold voltages. For example, the first transistor T1 formed in the first region R1 may have a threshold voltage lower than third transistors T3 formed in the third regions R3. The second transistor T2 formed in the second region R2 may have a threshold voltage lower than the first transistor T1 formed in the first region R1. The second transistor T2 formed in the second region R2 may have a threshold voltage lower than the third transistor T3 formed in the third region R3. The threshold voltages of the first to third transistors T1 to T3 may be determined respectively by the first, second, and third dipole interfaces 109A, 109B, and 109C.

A threshold voltage may differ depending on the content, i.e., type and/or concentration of dipole inducing chemical species contained in the first to third dipole interfaces 109A to 109C. For example, the lowest threshold voltage may be achieved based on a high concentration of diffused dipole inducing chemical species and the highest threshold voltage may be achieved based on a low concentration of diffused dipole inducing chemical species. The second dipole interface 109B of the second transistor T2 may have the highest concentration of dipole inducing chemical species and the third dipole interface 109C of the third transistor T3 may have the lowest concentration of dipole inducing chemical species. Thus, the threshold voltage of the third transistor T3 may be highest and the threshold voltage of the second transistor may be lowest. The third transistor T3 may have the highest threshold voltage because the third dipole interface 109C has the lowest concentration of dipole inducing chemical species which may be caused by an interference effect between the first and second N-type shifter layers 104 and 105 and the P-type shifter layer 106. In other word, an interference effect between an N-type dipole inducing material and a P-type dipole inducing material may suppress a diffusion of dipole inducing materials because the first and second N-type shifter layers 104 and 105 include an N-type dipole inducing material and the P-type shifter layer 106 includes a P-type dipole inducing material.

According to the embodiment of the present invention, different threshold voltages of NMOSFETs may be simultaneously controlled during an integration process of multiple NMOSFETs.

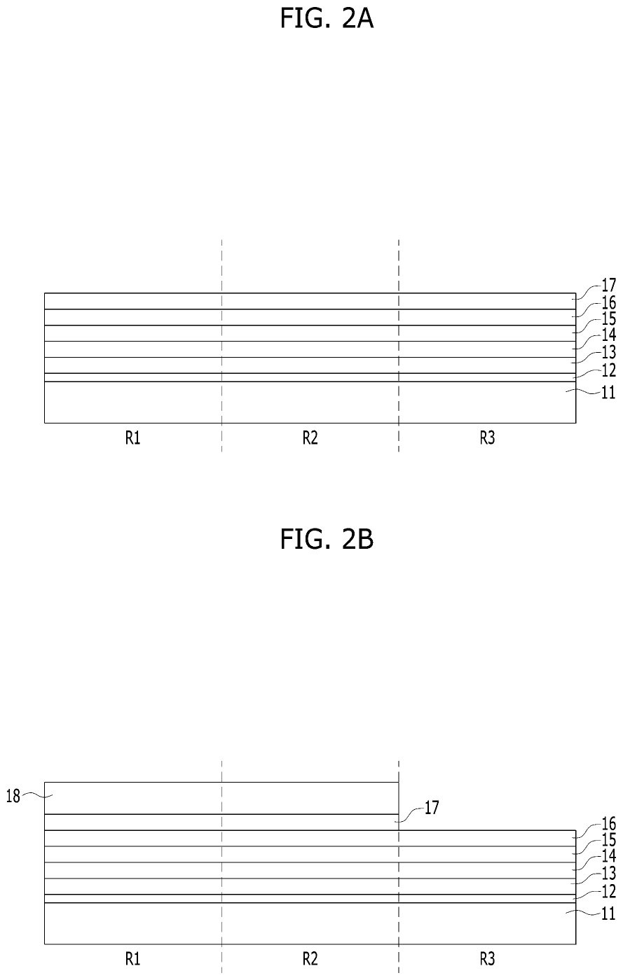

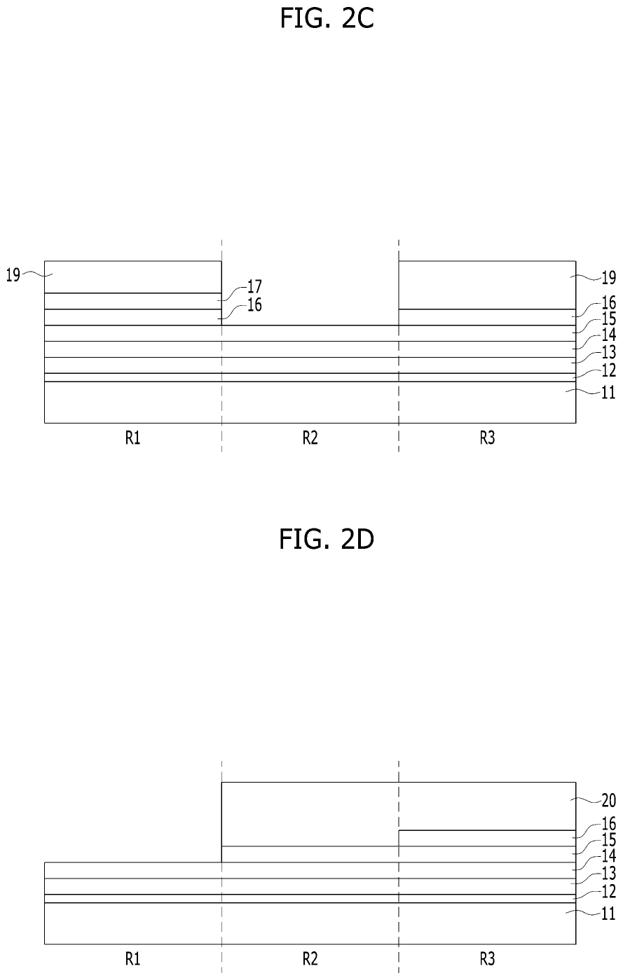

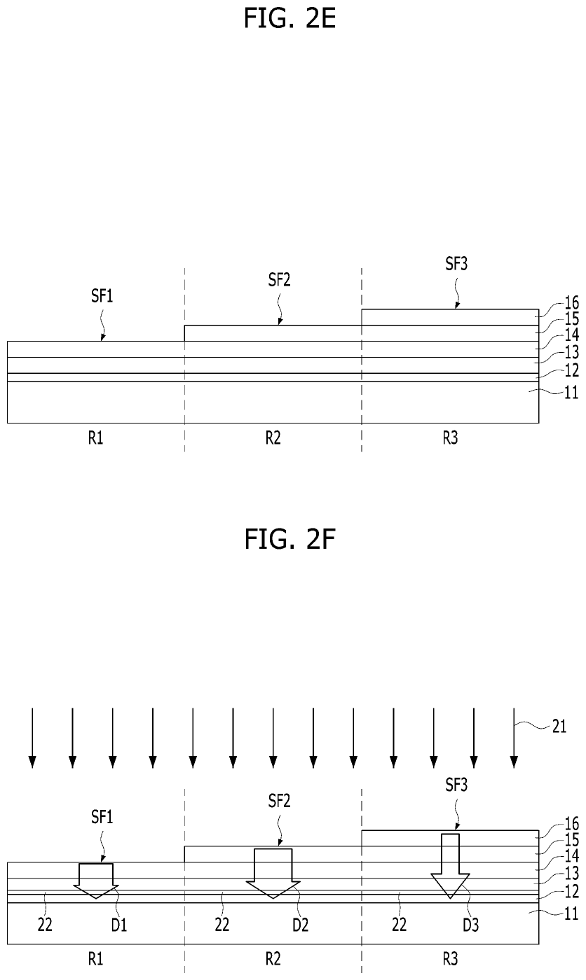

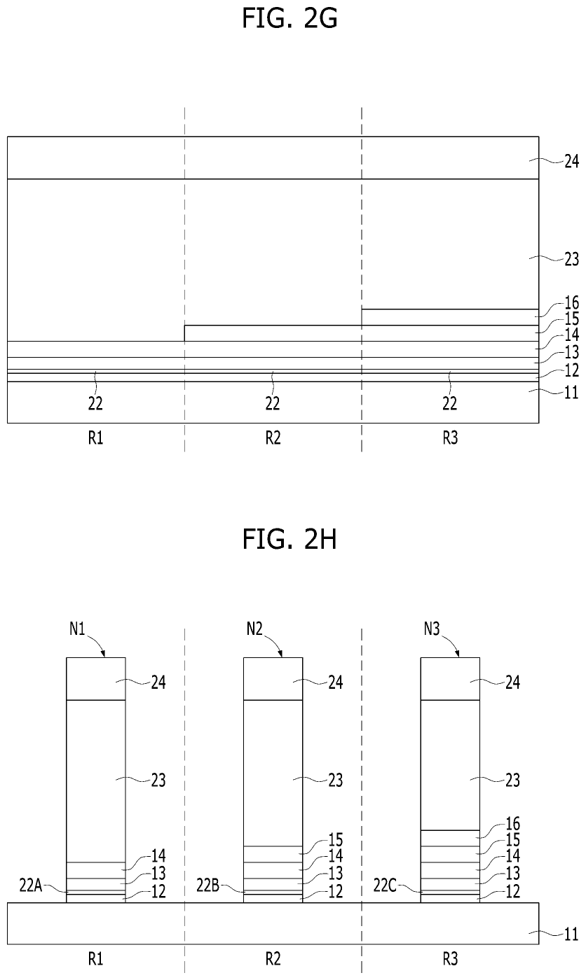

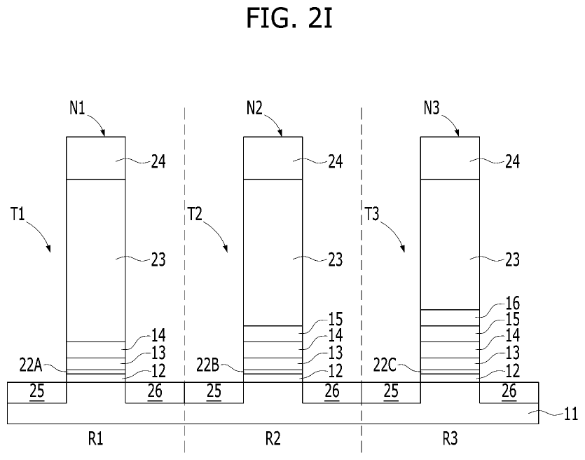

FIGS. 2A to 2I are diagrams illustrating a method for fabricating a semiconductor device according to an embodiment of the present invention.

In accordance with FIG. 2A, an interface layer 12 and a high-k dielectric layer 13 may be sequentially formed over a substrate 11.

The substrate 11 may include a first region R1, a second region R2, and a third region R3. Each of the first to third regions R1 to R3 may be regions where a transistor may be formed. Each of the first to third regions R1 to R3 may be regions where a N-channel transistor, such as NMOSFET, may be formed. Each of the first to third regions R1 to R3 may have a transistor having a different threshold voltage. Although not illustrated, the first to third regions R1 to R3 may be divided by an isolation layer.

For example, the substrate 11 may be formed of any suitable semiconductor material including a semiconductor substrate. For example, the substrate 11 may be formed of any suitable semiconductor material including silicon substrate, silicon germanium substrate, or silicon on insulator (SOI) substrate. The interface layer 12 may be formed of any suitable material including, for example, silicon oxide, silicon oxynitride, or a combination thereof. The high-k dielectric layer 13 and the interface layer 12 may be made of different materials. The high-k dielectric layer 13 may have a higher dielectric constant than the interface layer 12. The high-k dielectric layer 13 may be made of any suitable high-k material. For example, the high-k dielectric layer 13 may include hafnium oxide (HfO), hafnium silicon oxide (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicon oxide (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), plumbum scandium tantalum oxide (PbScTaO), or combinations thereof.

As illustrated above, the interface layer 12 may be formed on the first to third regions R1 to R3 at the same time.

A first shifter layer 14 may be formed over the high-k dielectric layer 13. The first shifter layer 14 may be formed of any suitable material including a dipole inducing material. The first shifter layer 14 may include a N-type dipole inducing material. The first shifter layer 14 may include a lanthanum-containing material. For example, the first shifter layer 14 may include lanthanum oxide.

A second shifter layer 15 may be formed over the first shifter layer 14. The second shifter layer 15 may be formed of any suitable material including a dipole inducing material. The second shifter layer 15 may include an N-type dipole inducing material. The second shifter layer 15 may include a lanthanum-containing material. For example, the second shifter layer 15 may include lanthanum oxide. The first shifter layer 14 and the second shifter layer 15 may be made of a same material.

A third shifter layer 16 may be formed over the second shifter layer 15. The third shifter layer 16 may be made of a material different from the material of the first and second shifter layers 14 and 15. The third shifter layer 16 may include a dipole inducing material. The third shifter layer 16 may include a P-type dipole inducing material. The third shifter layer 16 may include an aluminum-containing material. For example, the third shifter layer 16 may include, for example, aluminum oxide.

A fourth shifter layer 17 may be formed over the third shifter layer 16. The fourth shifter layer 17 may include a dipole inducing material. The fourth shifter layer 17 may include an N-type dipole inducing material. The fourth shifter layer 17 may include a lanthanum-containing material. For example, the fourth shifter layer 17 may include lanthanum oxide. The first, second, and fourth shifter layers 14, 15, and 17 may be made of a same material.

The first to fourth shifter layers 14 to 17 may have a same thickness. The first to fourth shifter layers 14 to 17 may be referred as a dipole inducing material layer.

Referring to FIG. 2B, a first mask layer 18 may be formed over the fourth shifter layer 17. The first mask layer 18 may include a photoresist pattern.

The first mask layer 18 may be used to remove the fourth shifter layer 17 from the third region R3.

In accordance with FIG. 2C, the first mask layer 18 may be removed. The first mask layer 18 may be removed by an ashing process using oxygen plasma. A cleaning process may be followed.

A second mask layer 19 may be formed. The second mask layer 19 may include a photoresist pattern.

In accordance with FIG. 2D, the second mask layer 19 may be removed. The second mask layer 19 may be removed by an ashing process using oxygen plasma. A cleaning process may be followed.

A third mask layer 20 may be formed. The third mask layer 20 may include a photoresist pattern. The third mask layer 20 may be used to remove the fourth shifter layer 17, the third shifter layer 16, and the second shifter layer 15 from the first region R1.

In accordance with FIG. 2E, the third mask layer 20 may be removed. The third mask layer 20 may be removed by an ashing process using oxygen plasma. A cleaning process may be followed.

Through a series of processes described above, a first, second, and third shifter structures SF1, SF2, and SF3 of different heights may be formed, respectively, over the first to third regions R1 to R3. The first shifter structure SF1 may be formed in the first region R1. The second shifter structure SF2 may be formed in the second region R2. The third shifter structure SF3 may be formed in the third region R3. The first shifter structure SF1 may be a single layer of the first shifter layer 14, the second shifter structure SF2 may be a double layer of the first shifter layer 14 and the second shifter layer 15, the third shifter structure SF3 may be a triple layer of the first shifter layer 14, the second shifter layer 15, and the third shifter layer 16. A single layer of an N-type dipole inducing material in the first region R1, double layers of an N-type dipole inducing material in the second region R2, and a stack of double layers of an N-type dipole inducing material and a single layer of a P-type dipole inducing material in the third region R3 may be formed.

In accordance with FIG. 2F, a post thermal treatment 21 may be performed. First, second, and third diffusions D1, D2, D3 of dipole inducing materials from the first to third shifter layers 14 to 16 may result from the post thermal treatment 21. Diffused dipole inducing materials may be disposed between the high-k dielectric layer 13 and the interface layer 12. The second diffusion D2 may include the largest diffusion concentration of dipole inducing materials and the third diffusion D3 may include the smallest diffusion concentration of dipole inducing materials. A diffusion concentration of the first diffusion D1 may be smaller than the second diffusion D2 and larger than the third diffusion D3. A difference in a concentration of the diffusions may be determined by a different stack composition of the first to third shifter layers 14 to 16.

As described above, a dipole interface 22 may be formed between the high-k dielectric layer 13 and the interface layer 12 through the post thermal treatment 21. The dipole interface 22 may be formed in each of the first to third regions R1 to R3. Each of the first to third shifter structures SF1 to SF3 may include the dipole interface 22.

In accordance with FIG. 2G, a gate layer 23 may be formed over the first to third shifter structures SF1 to SF3. The gate layer 23 may be formed of any suitable material including, for example, polysilicon, metal, metal nitride, or combinations thereof. For example, in an embodiment, the gate layer 23 may be sequentially stacked in the order of polysilicon, titanium oxide, and tungsten. In accordance with another embodiment of the present invention, the gate layer 23 may be sequentially stacked in the order of titanium nitride, tungsten, and polysilicon.

A gate capping layer 24 may be formed over the gate layer 23. The gate capping layer 24 may be formed of any suitable material including, for example, silicon nitride.

In accordance with FIG. 2H, a gate patterning process may be performed. Although not illustrated, a gate mask may be used to sequentially etch the gate capping layer 24, the gate layer 23, the first to third shifter structures SF1 to SF3, the high-k dielectric layer 13, and the interface layer 12. Accordingly, the first gate stack N1 may be formed over the first region R1 of the substrate 11, the second gate stack N2 may be formed over the second region R2 of the substrate 11, and the third gate stack N3 may be formed over the third region R3 of the substrate 11.

The first gate stack N1 may be sequentially stacked in the order of the interface layer 12, a first dipole interface 22A, the high-k dielectric layer 13, the first shifter layer 14, the gate layer 23, and the gate capping layer 24.

The second gate stack N2 may be sequentially stacked in the order of the interface layer 12, a second dipole interface 22B, the high-k dielectric layer 13, the first shifter layer 14, the second shifter layer 15, the gate layer 23, and the gate capping layer 24.

The third gate stack N3 may be sequentially stacked in the order of the interface layer 12, a third dipole interface 22C, the high-k dielectric layer 13, the first shifter layer 14, the second shifter layer 15, the third shifter layer 16, the gate layer 23, and the gate capping layer 24.

The interface layer 12, the high-k dielectric layer 13, the gate layer 23, and the gate capping layer 24 may be made of a same material in the first to third gate stacks N1 to N3. The first to third dipole interfaces 22A, 22B, and 22C may include dipole inducing chemical species in different concentrations.

In accordance with FIG. 2I, various processes known to a person of ordinary skill in the art may be performed following the gate patterning process. For example, a source/drain 25/26 formation process may be performed. The source/drain 25/26 may be formed in each of the first to third regions R1 to R3. The source/drain 25/26 may include an N-type dopant.

As described above, the first to third transistors T1 to T3 may be formed by forming the source/drain 25/26. The first transistor T1 may include the first gate stack N1 and the source/drain 25/26. The second transistor T2 may include the second gate stack N2 and the source/drain 25/26. The third transistor T3 may include the third gate stack N3 and the source/drain 25/26. The first to third transistors T1 to T3 may be N-channel transistors including NMOSFET type transistors.

The first to third transistors T1 to T3 may have different threshold voltages. For example, the first transistor T1 formed in the first region R1 may have a threshold voltage lower than the second and third transistors T2 and T3 respectively formed in the second and third regions R2 and R3. The second transistor T2 formed in the second region R2 may have a threshold voltage lower than the third transistor T3 formed in the third region R3. Different threshold voltages of the first to third transistors T1 to T3 may be respectively determined by the first to third dipole interfaces 22A to 22C.

A threshold voltage may vary depending on the content, i.e., the type and/or concentration of dipole inducing chemical species contained in the first to third dipole interfaces 22A to 22C. For example, the lowest threshold voltage may be achieved based on a high concentration of diffused dipole inducing chemical species and the highest threshold voltage may be achieved based on a low concentration of diffused dipole inducing chemical species.

The second dipole interface 22B of the second transistor T2 may have the highest concentration of dipole inducing chemical species, the third dipole interface 22C of the third transistor T3 may have the lowest concentration of dipole inducing chemical species. The concentration of dipole inducing chemical species in the first dipole interface 22A may be smaller than the concentration in the second dipole interface 22B and larger than the concentration in the third dipole interface 22C. Thus, the third transistor T3 may have the highest threshold voltage and the second transistor T2 may have the lowest threshold voltage. The first transistor T1 may have a threshold voltage higher than the second transistor T2 and lower than the third transistor T3. The third transistor T3 may have the highest threshold voltage because the third dipole interface 22C has the lowest concentration of dipole inducing chemical species which may be caused by an interference effect among the first to third shifter layers 14 to 16. Hence, an interference between an N-type dipole inducing material and a P-type dipole inducing material may suppress a diffusion of dipole inducing materials because the first and second shifter layers 14 and 15 include an N-type dipole inducing material and the third shifter 16 includes a P-type dipole inducing material.

In accordance with the illustrated embodiments of the present invention, direct or indirect damages, caused by a cleaning or an ashing process, on dipole interfaces or a high-k dielectric layer may be fundamentally prevented through a series of processes that sequentially remove shifter layers.

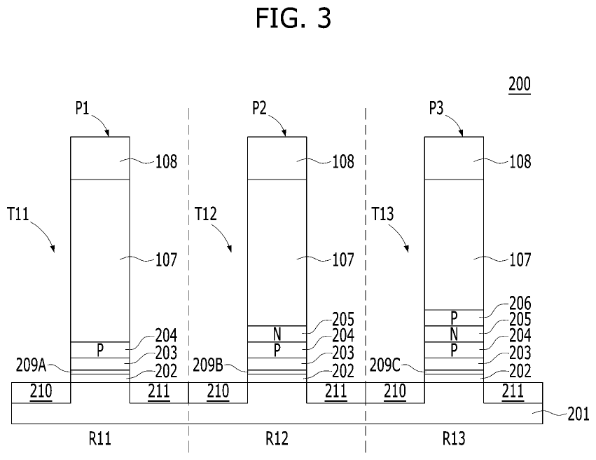

FIG. 3 is a diagram illustrating a semiconductor device according to another embodiment of the present disclosure.

Referring to FIG. 3, a semiconductor device 200 may include a first transistor T11, a second transistor T12, a third transistor T13. The first transistor T11 may be formed in a first region R11, the second transistor T12 may be formed in a second region R12, and the third transistor T13 may be formed in a third region R13. Each of the first to third transistors T11 to T13 may be a p type metal-oxide-semiconductor field-effect transistor (PMOSFET). Although not illustrated, the first to third transistors T11 to T13 may be divided by an isolation layer.

The first transistor T11 may include a first gate stack P1 formed over a substrate 201. The first transistor T11 may include a first source region 210 and a first drain region 211 formed on both sides of the first gate stack P1. The first gate stack P1 may be formed of an interface layer 202, a high-k dielectric layer 203, a first P-type shifter 204, a gate electrode 107, and a gate capping layer 108 which are sequentially stacked in the recited order. The first gate stack P1 may further include a first dipole interface 209A between the interface layer 202 and the high-k dielectric layer 203. The first dipole interface 209A may include dipole inducing chemical species for controlling a threshold voltage of the first transistor T11. As will be illustrated below, the first dipole interface 209A may be formed between the interface layer 202 and the high-k dielectric layer 203 through diffusion of dipole inducing chemical species from the first P-type shifter 204 containing dipole inducing chemical species. The threshold voltage of the first transistor T11 is controlled by the first dipole interface 209A. The first dipole interface 209A may include, for example, aluminum (Al).

The second transistor T12 may include a second gate stack P2 formed over the substrate 201. The second transistor T12 may include the first source region 210 and the first drain region 211 formed on both sides of the second gate stack P2. The second gate stack P2 may be formed to include the interface layer 202, the high-k dielectric layer 203, the first P-type shifter 204, an N-type shifter 205, the gate electrode 107, and the gate capping layer 108 which are sequentially stacked in the recited order. The second gate stack P2 may further include a second dipole interface 209B between the interface layer 202 and the high-k dielectric layer 203. The second dipole interface 209B may include dipole inducing chemical species for controlling a threshold voltage of the second transistor T12. As will be illustrated below, the second dipole interface 209B may be formed between the interface layer 202 and the high-k dielectric layer 203 through diffusion of dipole inducing chemical species from the first P-type shifter 204 containing dipole inducing chemical species. The threshold voltage of the second transistor T12 is controlled by the second dipole interface 209B. The second dipole interface 209B may include, for example, aluminum (Al).

The third transistor T13 may include a third gate stack P3 formed over the substrate 201. The third transistor T13 may include the first source region 210 and the first drain region 211 formed on both sides of the third gate stack P3. The third gate stack P3 may be formed to include the interface layer 202, the high-k dielectric layer 203, the first P-type shifter 204, the N-type shifter 205, a second P-type shifter 206, the gate electrode 107, and the gate capping layer 108 which are sequentially stacked in the recited order. The third gate stack P3 may further include a third dipole interface 209C formed between the interface layer 202 and the high-k dielectric layer 203. The third dipole interface 209C may include dipole inducing chemical species for controlling a threshold voltage of the third transistor T13. As will be illustrated below, the third dipole interface 209C may be formed between the interface layer 202 and the high-k dielectric layer 203 through diffusion of dipole inducing chemical species from the first and second P-type shifters 204 and 206 containing dipole inducing chemical species. The threshold voltage of the third transistor T13 is controlled by the third dipole interface 209C. The third dipole interface 209C may include, for example, aluminum (Al).

In accordance with FIG. 3, the first to third transistors T11 to T13 may have different threshold voltages. For example, the first transistor T11 formed in the first region R11 may have a lower threshold voltage than the second transistor T12 and the third transistor T13 which are respectively formed in the second and third regions R12 and R13. The second transistor T12 formed in the second region R12 may have a higher threshold voltage than the third transistor T13 formed in the third region R13. The threshold voltages of the first to third transistors T11 to T13 may be determined respectively by the first, second, and third dipole interfaces 209A, 209B, and 209C.

A threshold voltage may vary depending on the content, i.e., the type and/or concentration of dipole inducing chemical species contained in the first to third dipole interfaces 109A to 109C. For example, the lowest threshold voltage may be achieved based on a high concentration of dipole inducing chemical species and the highest threshold voltage may be achieved based on a low concentration of diffused dipole inducing chemical species. The first dipole interface 209A of the first transistor T11 may have the highest concentration of dipole inducing chemical species and the second dipole interface 209B of the second transistor T12 may have the lowest concentration of dipole inducing chemical species. Thus, the second transistor T12 may have the highest threshold voltage and the first transistor T11 may have the lowest threshold voltage. The third transistor T13 may have a threshold voltage higher than the first transistor T11 and lower than the second transistor T12. A threshold voltage of the first transistor T11 may have a threshold voltage lower than the second and third transistors T12 and T13 because an interference between the first and second P-type shifters 204 and 206 and the N-type shifter 205 does not exist.

The third transistor T13 may have a threshold voltage higher than the first transistor T11 because the third dipole interface 209C has a smaller diffusion concentration of dipole inducing chemical species than the first dipole interface 209A, which may be caused by an interference effect between the first and second P-type shifters 204 and 206 and the N-type shifter 205.

The second transistor T12 may have the highest threshold voltage because the second dipole interface 209B has a smaller diffusion concentration of dipole inducing chemical species than the first and third dipole interfaces 209A and 209C, which may be caused by an interference effect between the first P-type shifter 204 and the N-type shifter 205.

As described above, an interference between an N-type dipole inducing material and a P-type dipole inducing material may suppress a diffusion of dipole inducing materials because the N-type shifter 205 includes an N-type dipole inducing material and the first and second P-type shifters 204 and 206 include a P-type dipole inducing material.

In accordance with the embodiment of the present invention, different threshold voltages of PMOSFETs may be simultaneously controlled during an integration process of multiple PMOSFETs.

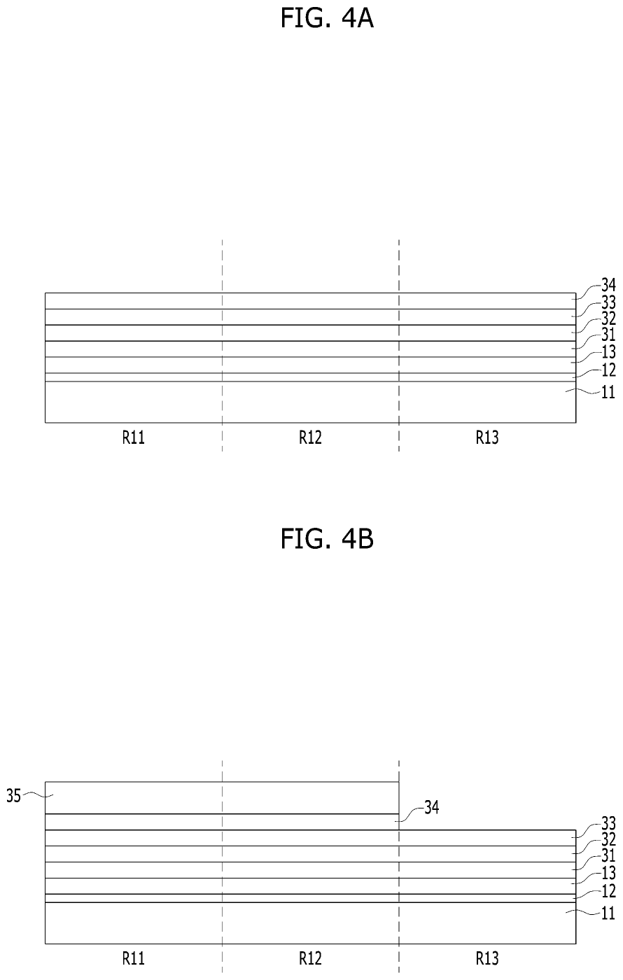

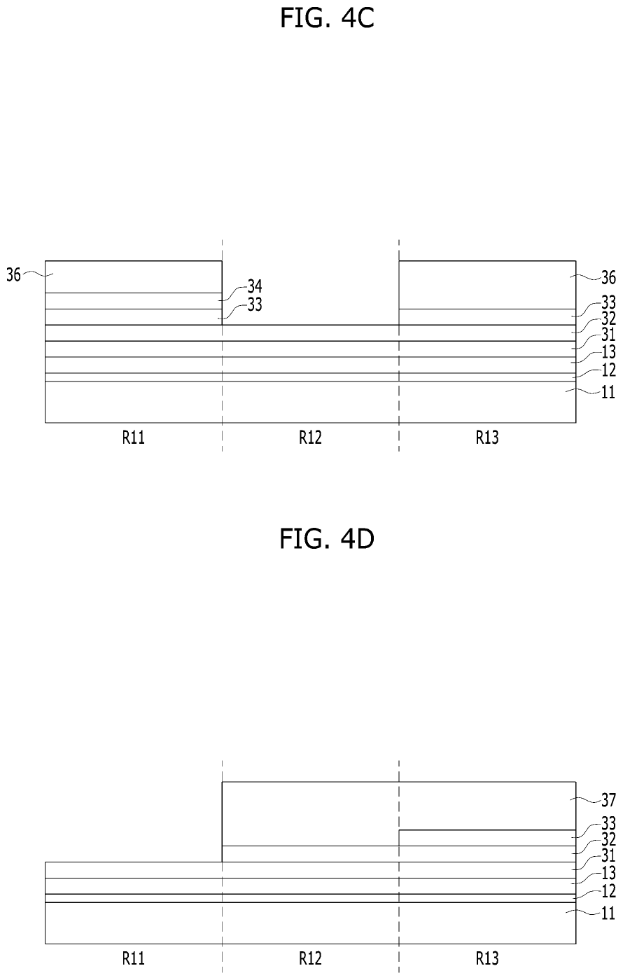

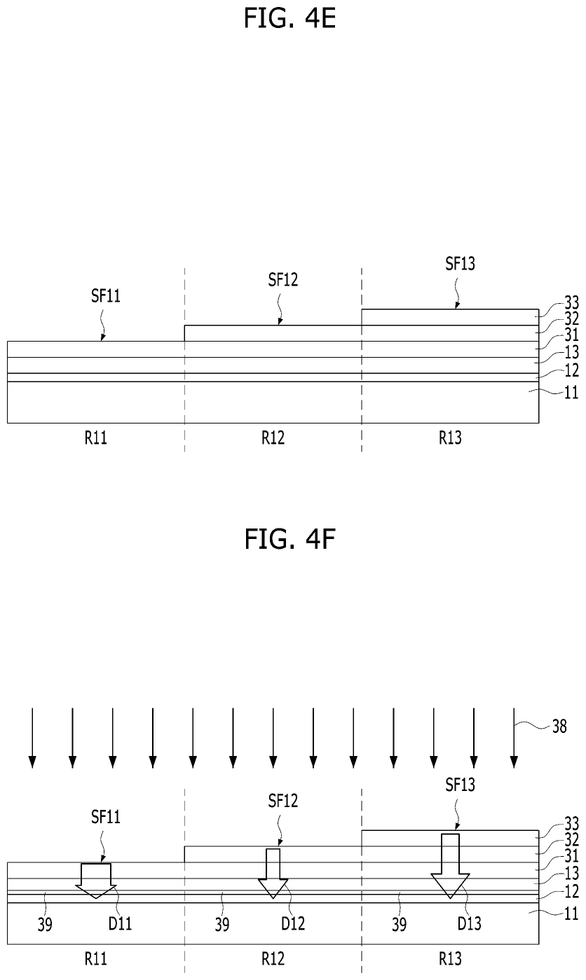

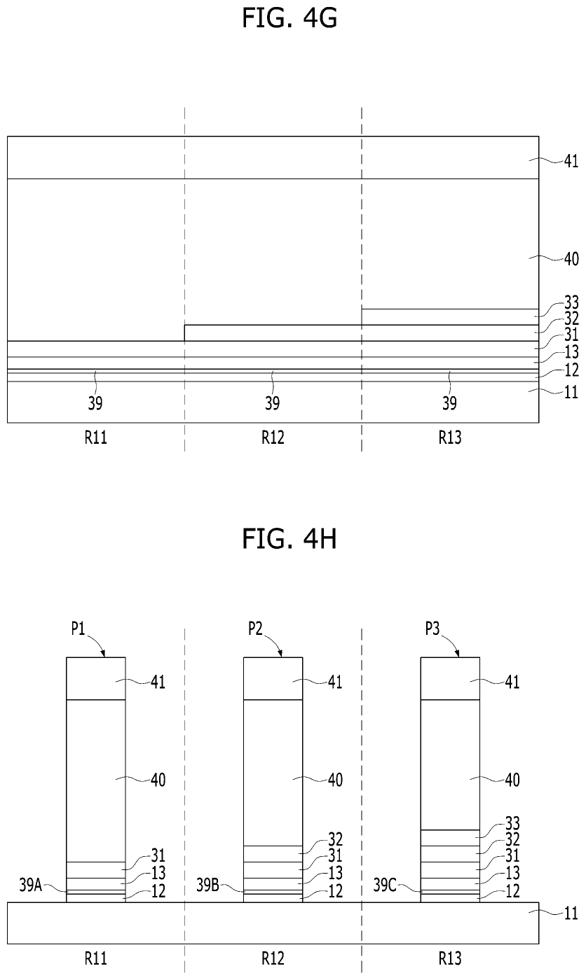

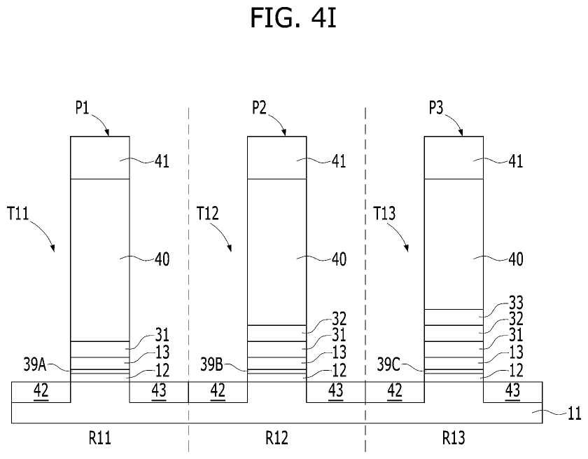

FIGS. 4A to 4I are diagrams illustrating a method for fabricating a semiconductor device according to another embodiment of the present invention. The components illustrated in FIGS. 4A to 4I and indicated by the same reference numerals as in FIGS. 2A to 2I may be those of the reference numerals as described with reference to FIGS. 2A to 2I.

As illustrated in FIG. 4A, an interface layer 12 and a high-k dielectric layer 13 may be sequentially formed over a substrate 11.

The substrate 11 may include a first region R11, a second region R12, and a third region R13. The first to third regions R11 to R13 may be respective regions where a transistor may be formed. The first to third regions R11 to R13 may be respective regions where a P-channel transistor, such as PMOSFET, may be formed. The first to third regions R11 to R13 may be regions where transistors with different threshold voltages may be formed. Although not illustrated, the first to third regions R11 to R13 may be divided by an isolation layer.

The substrate 11 may be a semiconductor substrate. The substrate 11 may be formed of any suitable semiconductor material including silicon substrate, silicon germanium substrate, or silicon on insulator (SOI) substrate. The interface layer 12 may be formed of any suitable material including, for example, silicon oxide, silicon oxynitride, or a combination thereof. The high-k dielectric layer 13 and the interface layer 12 may be made of different materials. The high-k dielectric layer 13 may have a higher dielectric constant than the interface layer 12. The high-k dielectric layer 13 may include a high-k material. For example, the high-k dielectric layer 13 may include hafnium oxide (HfO), hafnium silicon oxide (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicon oxide (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), plumbum scandium tantalum oxide (PbScTaO), or combinations thereof.

As illustrated above, the interface layer 12 and the high-k dielectric layer 13 may be formed over the first to third regions R11 to R13.

A first shifter layer 31 may be formed over the high-k dielectric layer 13. The first shifter layer 31 may include a dipole inducing material. The first shifter layer 31 may include a P-type dipole inducing material. In an embodiment, the first shifter layer 31 may include an aluminum-containing material. For example, the first shifter layer 31 may include, for example, aluminum oxide.

A second shifter layer 32 may be formed over the first shifter layer 31. The second shifter layer 32 may include a dipole inducing material. The second shifter layer 32 may include an N-type dipole inducing material. The second shifter layer 32 may include a lanthanum-containing material. For example, the second shifter layer 32 may include lanthanum oxide. The first shifter layer 31 and the second shifter layer 32 may be made of different materials.

A third shifter layer 33 may be formed over the second shifter layer 32. The third shifter layer 33 and the first shifter layer 31 may be made of a same material. The third shifter layer 33 may include a dipole inducing material. The third shifter layer 33 may include a P-type dipole inducing material. In an embodiment, the third shifter layer 33 may include an aluminum-containing material. For example, the third shifter layer 33 may include, for example, aluminum oxide.

A fourth shifter layer 34 may be formed over the third shifter layer 33. The fourth shifter layer 34 may include a dipole inducing material. The fourth shifter layer 34 may include a P-type dipole inducing material. The fourth shifter layer 34 may include an aluminum-containing material. For example, the fourth shifter layer 34 may include, for example, aluminum oxide. The first, third, and fourth shifter layers 31, 33, and 34 may be made of a same material.

The first to fourth shifter layers 31 to 34 may have a same thickness. The first to fourth shifter layers 31 to 34 may be referred as a dipole inducing material layer.

In accordance with FIG. 4B, a first mask layer 35 may be formed over the fourth shifter layer 34. The first mask layer 35 may include a photoresist pattern.

The first mask layer 35 may be used to remove the fourth shifter layer 34 from the third region R13.

In accordance with FIG. 4C, the first mask layer 35 may be removed. The first mask layer 35 may be removed by an ashing process using oxygen plasma.

A second mask layer 36 may be formed. The second mask layer 36 may include a photoresist pattern.

The second mask layer 36 may be used to remove the fourth shifter layer 34 and the third shifter layer 33 from the second region R12.

In accordance with FIG. 4D, the second mask layer 36 may be removed. The second mask layer 36 may be removed by an ashing process using oxygen plasma. A cleaning process may be followed.

A third mask layer 37 may be formed. The third mask layer 37 may include a photoresist pattern.

The third mask layer 37 may be used to remove the fourth shifter layer 34, the third shifter layer 33, and the second shifter layer 32 from the first region R11.

In accordance with FIG. 4E, the third mask layer 37 may be removed. The third mask layer 37 may be removed by an ashing process using oxygen plasma. A cleaning process may be followed.

Through a series of processes described above, a first shifter structure SF11, a second shifter structure SF12, and a third shifter structure SF13 of different heights may be formed respectively over the first to third regions R11 to R13. The first shifter structure SF11 may be formed in the first region R11. The second shifter structure SF12 may be formed in the second region R12. The third shifter structure SF13 may be formed in the third region R13. The first shifter structure SF11 may be a single layer of the first shifter layer 31, and the second shifter structure SF12 may be a double layer structure having the first shifter layer 31 and the second shifter layer 32. The third shifter structure SF13 may be a stack of the first shifter layer 31, the second shifter layer 32, and the third shifter layer 33. A single layer of a P-type dipole inducing material in the first region R11, double layers of a P-type dipole inducing material and an N-type dipole inducing material in the second region R12, and a triple layer stack of double layers of a P-type dipole inducing material and a single layer of an N-type dipole inducing material in the third region R13 may be formed.

In accordance with FIG. 4F, a post thermal treatment 38 may be performed. First, second, and third diffusions D12, D12, D13 of dipole inducing materials from the first to third shifter layers 31 to 33 may result from the post thermal treatment 38. Diffused dipole inducing materials may be disposed between the high-k dielectric layer 13 and the interface layer 12. The first diffusion D11 may include the largest diffusion concentration of dipole inducing materials and the second diffusion D12 may include the smallest diffusion concentration of dipole inducing materials. The third diffusion D13 may include a diffusion concentration smaller than the first diffusion D11 and larger than the second diffusion D12. A difference in a diffusion concentration may be based on an interference among the first to third shifter layers 31 to 33.

As described above, a dipole interface 39 may be formed between the high-k dielectric layer 13 and the interface layer 12 through the post thermal treatment 38. The dipole interface 39 may be formed in each of the first to third regions R11 to R13. Each of the first to third shifter structures SF11 to SF13 may include the dipole interface 39.

In accordance with FIG. 4G, a gate layer 40 may be formed over the first to third shifter structures SF11 to SF13. The gate layer 40 may be formed of any suitable material including, for example, polysilicon, metal, metal nitride, or combinations thereof. For example, in an embodiment, the gate layer 40 may be sequentially stacked in the order of polysilicon, titanium oxide, and tungsten. In accordance with another embodiment of the present invention, the gate layer 40 may be sequentially stacked in the order of titanium nitride, tungsten, and polysilicon.

A gate capping layer 41 may be formed over the gate layer 40. The gate capping layer 41 may include, for example, silicon nitride.

In accordance with FIG. 4H, a gate patterning process may be performed. Although not illustrated, a gate mask may be used to sequentially etch the gate capping layer 41, the gate layer 40, the first to third shifter structures SF11 to SF13, the high-k dielectric layer 13, and the interface layer 12. Accordingly, a first gate stack P1 may be formed over the first region R11 of the substrate 11, a second gate stack P2 may be formed over the second region R12 of the substrate 11, and the third gate stack P3 may be formed over the third region R13 of the substrate 11.

The first gate stack P1 may be sequentially stacked in the order of the interface layer 12, a first dipole interface 39A, the high-k dielectric layer 13, the first shifter layer 31, the gate layer 40, and the gate capping layer 41.

The second gate stack P2 may be sequentially stacked in the order of the interface layer 12, a second dipole interface 39B, the high-k dielectric layer 13, the first shifter layer 31, the second shifter layer 32, the gate layer 40, and the gate capping layer 41.

A third gate stack P3 may be sequentially stacked in the order of the interface layer 12, a third dipole interface 39C, the high-k dielectric layer 13, the first shifter layer 31, the second shifter layer 32, the third shifter layer 33, the gate layer 40, and the gate capping layer 41.

In accordance with FIG. 41, various processes known to a person of ordinary skill in the art may be performed following the gate patterning process. For example, a source/drain 42/43 formation process may be performed. The source/drain 42/43 may be formed in each of the first to third regions R11 to R13. The source/drain 42/43 may include, for example, a P-type dopant.

As described above, the first to third transistors T11 to T13 may be formed by forming the source/drain 25/26. The first transistor T11 may include the first gate stack P1 and the source/drain 42/43. The second transistor T12 may include the second gate stack P2 and the source/drain 42/43. The third transistor T13 may include the third gate stack P3 and the source/drain 42/43. The first to third transistors T11 to T13 may be, for example, P-channel transistors including PMOSFET type transistors.

The first to third transistors T11 to T13 may have different threshold voltages. For example, the first transistor T11 formed in the first region R11 may have a threshold voltage lower than the second and third transistors T12 and T13 respectively formed in the second and third regions R12 and R13. The third transistor T13 formed in the third region R13 may have a threshold voltage lower than the second transistor T12 formed in the second region R12. The threshold voltages of the first to third transistors T11 to T13 may be determined respectively by the first to third dipole interfaces 39A to 39C.

A threshold voltage may vary depending on the content, i.e., the type and/or concentration of dipole inducing chemical species contained in the first to third dipole interfaces 39A to 39C. For example, the lowest threshold voltage may be achieved based on a high concentration of diffused dipole inducing chemical species and the highest threshold voltage may be achieved based on a low concentration of diffused dipole inducing chemical species.

The second dipole interface 39B of the second transistor T12 may have the lowest concentration of dipole inducing chemical species, and the first dipole interface 39A of the first transistor T11 may have the highest concentration of dipole inducing chemical species. Thus, the second transistor T12 may have the highest threshold voltage and the first transistor T11 may have the lowest threshold voltage. The third transistor T13 may have a threshold voltage higher than the first transistor T11 and lower than the second transistor T12.

The threshold voltage of the first transistor T11 is lower than the second and third transistors T12 and T13 because an interference between the first and third shifter layers 31 and 33 and the second shifter layer 32 does not exist. In other words, the threshold voltage of the first transistor T11 may be lowest because the highest concentration of a P-type dipole inducing material diffuses in the first dipole interface 39A.

The third transistor T13 may have a threshold voltage higher than the first transistor T11 because the third dipole interface 39C has a smaller diffusion concentration of dipole inducing chemical species than the first dipole interface 39A, which may be caused by an interference effect between the first and third shifter layers 31 and 33 and the second shifter layer 32.

The second transistor T12 may have the highest threshold voltage because the second dipole interface 39B has a smaller diffusion concentration of dipole inducing chemical species than the first and third dipole interfaces 39A and 39C, which may be caused by an interference effect between the first shifter layer 31 and the second shifter layer 32.

As described above, an interference between an N-type dipole inducing material and a P-type dipole inducing material may suppress a diffusion of dipole inducing materials because the first and third shifter layers 31 and 33 include a P-type dipole inducing material and the second shifter layer 32 includes an N-type dipole inducing material.

In accordance with an embodiment of the present invention, different threshold voltages of PMOSFETs may be simultaneously controlled during an integration process of multiple PMOSFETs.

In accordance with an embodiment of the present invention, direct or indirect damages, caused by a cleaning or an ashing process, on dipole interfaces or a high-k dielectric layer may be fundamentally prevented through a series of processes that sequentially remove shifter layers.

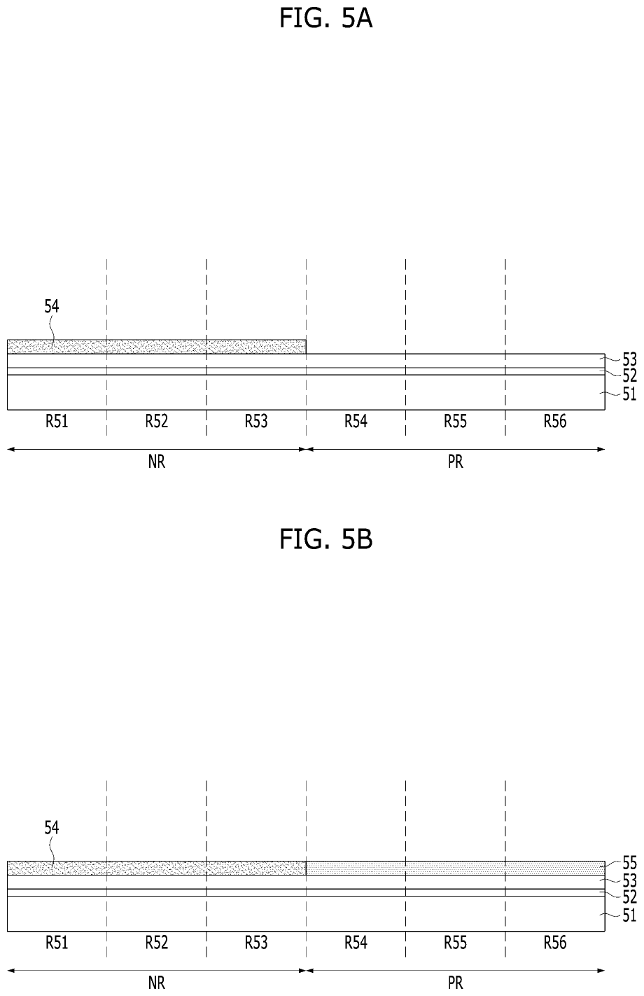

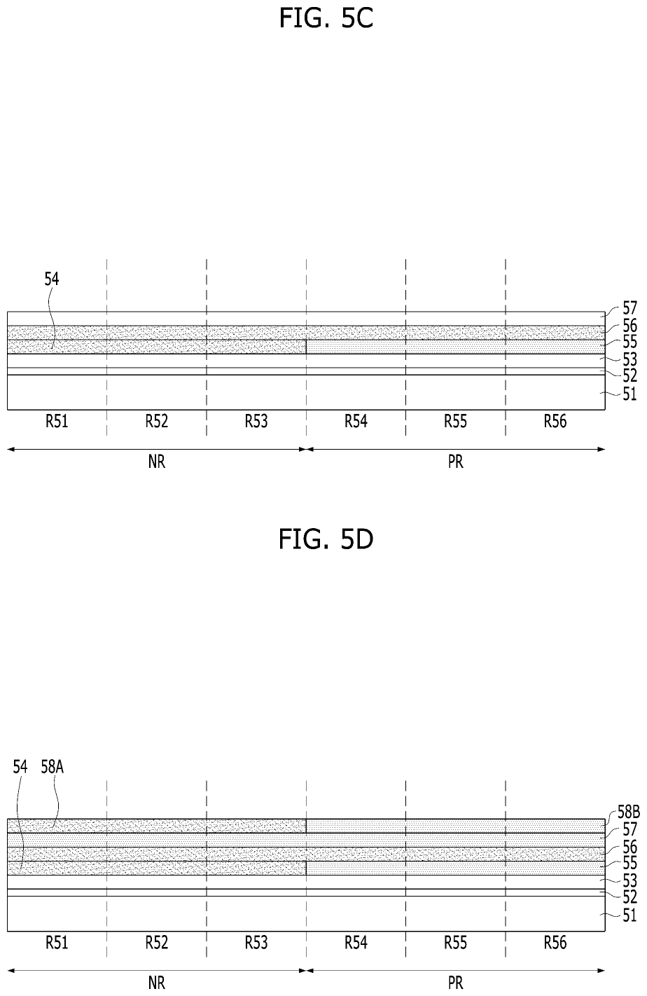

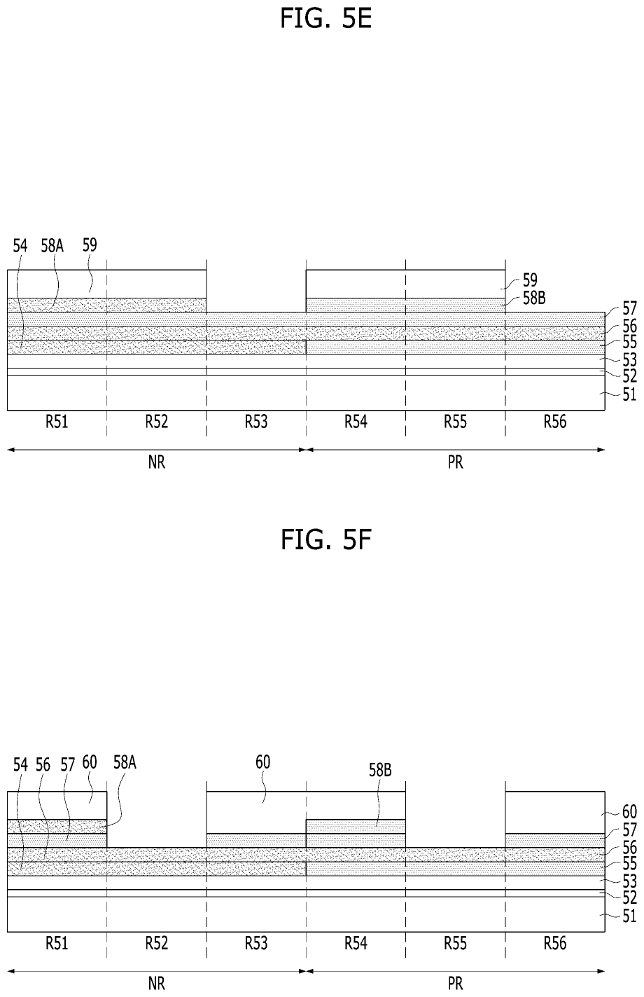

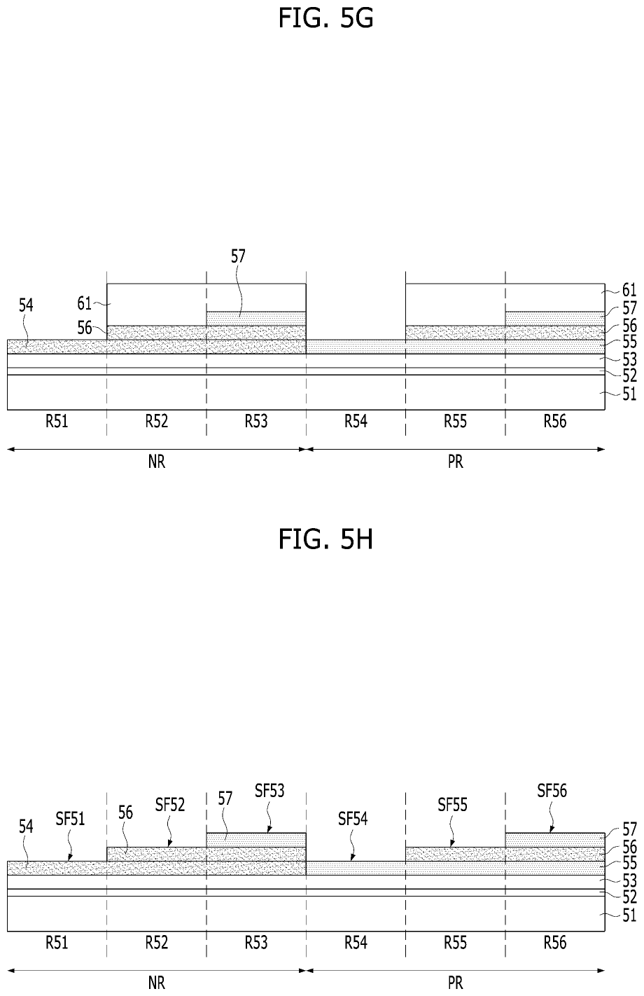

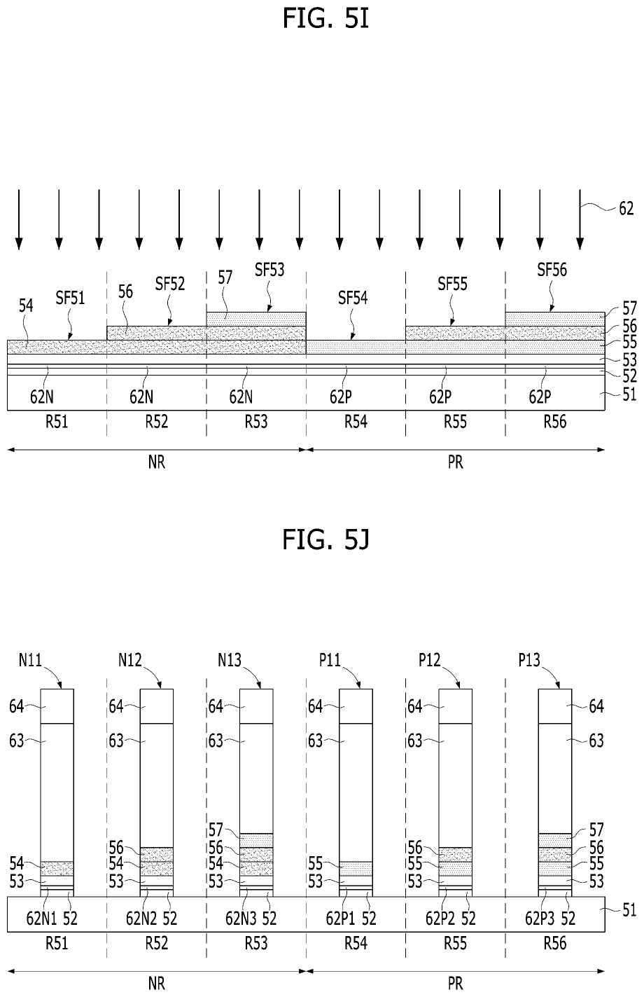

FIGS. 5A to 5J are diagrams illustrating another method for fabricating a semiconductor device according to an embodiment of the present invention. The components illustrated in FIGS. 5A to 5J and indicated by the same reference numerals as in FIGS. 2A to 2I and 4A to 4I may be those of the reference numerals as described with reference to FIGS. 2A to 2I and 4A to 4I.

As illustrated in FIG. 5A, an interface layer 52 and a high-k dielectric layer 53 may be sequentially formed over a substrate 51.

The substrate 51 may include a N-channel transistor region NR and a P-channel transistor region PR. The N-channel transistor region NR may include a first region R51, a second region R52, and a third region R53. The P-channel transistor region PR may include a fourth region R54, a fifth region R55, and a sixth region R56. The first to third regions R51 to R53 may be regions where N-channel transistors with different threshold voltages may be formed. The fourth to sixth regions R54 to R56 may be regions where P-channel transistors with different threshold voltages may be formed. Although not illustrated, the first to sixth regions R51 to R56 may be divided by an isolation layer.

The substrate 51 may be any suitable substrate including a semiconductor substrate. The substrate 51 may include silicon substrate, silicon germanium substrate, or silicon on insulator (SOI) substrate. The interface layer 52 may include silicon oxide, silicon oxynitride, or a combination thereof. The high-k dielectric layer 53 and the interface layer 52 may be made of different materials. The high-k dielectric layer 53 may have a higher dielectric constant than the interface layer 52. The high-k dielectric layer 53 may include a high-k material. For example, the high-k dielectric layer 53 may include hafnium oxide (HfO), hafnium silicon oxide (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicon oxide (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), plumbum scandium tantalum oxide (PbScTaO), or combinations thereof.

As illustrated above, the interface layer 52 and the high-k dielectric layer 53 may be formed over the first to sixth regions R51 to R56 at the same time.

A first N-type shifter layer 54 may be formed over the high-k dielectric layer 53 of the N-channel transistor region NR. The first N-type shifter layer 54 may include an N-type dipole inducing material. The first N-type shifter layer 54 may include a lanthanum-containing material. For example, the first N-type shifter layer 54 may include lanthanum oxide. The first N-type shifter layer 54 may be selectively formed in the first to third regions R51 to R53. The first N-type shifter layer may not be formed in the fourth to sixth regions R54 to R56.

As illustrated in FIG. 5B, a first P-type shifter layer 55 may be formed over the high-k dielectric layer 53 of the P-channel transistor region PR. The first P-type shifter layer 55 may include a P-type dipole inducing material. The first P-type shifter layer 55 may include an aluminum-containing material. For example, the first P-type shifter layer 55 may include aluminum oxide. The first N-type shifter layer 54 and the first P-type shifter layer 55 may be made of different materials.

As illustrated in FIG. 5C, a second N-type shifter layer 56 may be formed over the first N-type shifter layer 54 and the first P-type shifter layer 55. The second N-type shifter layer 56 and the first N-type shifter layer 54 may be made of a same material. The second N-type shifter layer 56 and the first P-type shifter layer 55 may be made of different materials. The second N-type shifter layer 56 may include an N-type dipole inducing material. The second N-type shifter layer 56 may include a lanthanum-containing material. For example, the second N-type shifter layer 56 may include lanthanum oxide.

A second P-type shifter layer 57 may be formed over the second N-type shifter layer 56. The second P-type shifter layer 57 may include a P-type dipole inducing material. The second P-type shifter layer 57 may include, for example, aluminum-containing material. For example, the second P-type shifter layer 57 may include aluminum oxide.

The first N-type shifter layer 54 and the second N-type shifter layer 56 may be made of a same material. The first P-type shifter layer 55 and the second P-type shifter layer 57 may be made of a same material.

As illustrated in FIG. 5D, a first sacrificial shifter layer 58A may be formed over the second N-type shifter layer 56. A second sacrificial shifter layer 58B may be formed over the second P-type shifter layer 57. The first sacrificial shifter layer 58A may include an N-type dipole inducing material and the second sacrificial shifter layer 58B may include a P-type dipole inducing material.

As illustrated in FIG. 5E, a first mask layer 59 may be formed over the first and second sacrificial shifter layers 58A and 58B. The first mask layer 59 may include a photoresist pattern.

The first mask layer 59 may be used to remove the first sacrificial shifter layer 58A from the third region R53. The first mask layer 59 may be used to remove the second sacrificial layer 58B from the sixth region R56. A cleaning process may be followed.

As the first and second sacrificial shifter layers 58A and 58B are respectively removed from the third and sixth regions R53 and R56 at the same time, a manufacturing process may be simplified. Also, the first N-type shifter layer 54, the first P-type shifter layer 55, and the high-k dielectric layer 53 are not damaged by an ashing and a cleaning process.

As illustrated in FIG. 5F, the first mask layer 59 may be removed. The first mask layer 59 may be removed by an ashing process using oxygen plasma. A cleaning process may be followed.

A second mask layer 60 may be formed. The second mask layer 60 may include a photoresist pattern.

The second mask layer 60 may be used to remove the first sacrificial layer 58A and the second P-type shifter layer 57 from the second region R52. The second mask layer 60 may be used to remove the second sacrificial shifter layer 58B and the second P-type shifter layer 57 from the fifth region R55. A cleaning process may be followed. Also, the first N-type shifter layer 54, the first P-type shifter layer 55, and the high-k dielectric layer 53 are not damaged by an ashing and a cleaning process.

As the first sacrificial shifter layer 58A and the second sacrificial shifter layer 58B are respectively removed from the second and fifth regions R52 and R55 at the same time, a manufacturing process may be simplified.

As illustrated in FIG. 5G, the second mask layer 60 may be removed. The second mask layer 60 may be removed by an ashing process using oxygen plasma. A cleaning process may be followed.

A third mask layer 61 may be formed. The third mask layer 61 may include a photoresist pattern.

The third mask layer 61 may be used to remove the second N-type shifter layer 56, the second P-type shifter layer 57, and the first sacrificial layer 58A from the first region R51. The third mask layer 61 may be used to remove the second N-type shifter layer 56, the second P-type shifter layer 57, and the second sacrificial shifter layer 58B from the fourth region R54. A cleaning process may be followed.

As the second N-type shifter layer 56, the second P-type shifter layer 57, and the first sacrificial shifter layer 58A from the first region R51 and the second N-type shifter layer 56, the second P-type shifter layer 56, and the second sacrificial shifter layer 58B from the fourth region R54 may be removed at the same time, a manufacturing process may be simplified. Also, the first N-type shifter layer 54, the first P-type shifter layer 55, and the high-k dielectric layer 53 are not damaged from an ashing and a cleaning process.

As illustrated in FIG. 5H, the third mask layer 61 may be removed. The third mask layer 61 may be removed by an ashing process using oxygen plasma. A cleaning process may be followed.

Through a series of processes described above, first, second, and third N-type shifter structures SF51, SF52, and SF53 of different heights may be respectively formed over the first to third regions R51 to R53. Fourth, fifth, and sixth P-type shifter structures SF54, SF55, and SF56 of different heights may be respectively formed over the fourth to sixth regions R54 to R56.

The first shifter structure SF51 may be a single layer of the first N-type shifter layer 54, and the second shifter structure SF52 may be double layers of the first N-type shifter layer 54 and the second N-type shifter layer 56. The third shifter structure SF53 may be a stack of the first N-type shifter layer 54, the second N-type shifter layer 56, and the second P-type shifter layer 57. A single layer of an N-type dipole inducing material may be formed in the first region R51, double layers of an N-type dipole inducing material may be formed in the second region R52, and a stack of double layers of an N-type dipole inducing material and a single layer of a P-type dipole inducing material may be formed in the third region R53.

The fourth shifter structure SF54 may be a single layer of the first P-type shifter layer 55. The fifth shifter structure SF55 may be double layers of the first P-type and the second N-type shifter layers 55 and 56. The sixth shifter structure SF56 may be a stack of the first P-type shifter layer 55, the second N-type shifter layer 56, and the second P-type shifter layer 57. A single layer of a P-type dipole inducing material may be formed in the fourth region R54, double layers of a P-type and an N-type dipole inducing material may be formed in the fifth region R55, and a triple layer stack of double layers of a P-type dipole inducing material and a single layer of an N-type dipole inducing material may be formed in the sixth region R56.

In accordance with FIG. 51, a post thermal treatment 62 may be performed. Dipole inducing materials may be diffused through the post thermal treatment 62. Diffused dipole inducing materials may be disposed between the high-k dielectric layer 53 and the interface layer 52.

Through the post thermal treatment 62 as described above, an N-type dipole interface 62N and a P-type dipole interface 62P may be formed between the high-k dielectric layer 53 and the interface layer 52. Each of the first to third shifter structures SF51 to SF53 may include an N-type dipole interface 62N. Each of the fourth to sixth shifter structures SF54 to SF56 may include a P-type dipole interface 62P.

As illustrated in FIG. 5J, a gate layer 63 and a gate capping layer 64 may be formed. The gate layer 63 may include polysilicon, metal, metal nitride, or combinations thereof. For example, the gate layer 63 may be sequentially stacked in the order of polysilicon, titanium nitride, and tungsten. In another embodiment of the invention, the gate layer 63 may be sequentially stacked in the order of titanium nitride, tungsten, and polysilicon.

The gate capping layer 64 may include silicon nitride.

A gate patterning process may be performed after the gate capping layer 64 is formed. Although not illustrated, a gate mask may be used to sequentially etch the gate capping layer 64, the gate layer 63, the first to third shifter structures SF51 to SF53, the fourth to sixth shifter structures SF54 to SF56, the high-k dielectric layer 53, and the interface layer 52. Accordingly, a first N-type gate stack N11 may be formed over the first region R51 of the substrate 51, a second N-type gate stack N12 may be formed over the second region R52 of the substrate 51, and a third N-type gate stack N13 may be formed over the third region R53 of the substrate 51. A first P-type gate stack P11 may be formed over the fourth region R54 of the substrate 51, a second P-type gate stack P12 may be formed over the fifth region R55 of the substrate 51, and a third P-type gate stack P13 may be formed over the sixth region R56 of the substrate 51.

The first N-type gate stack N11 may be sequentially stacked in the order of the interface layer 52, a first N-type dipole interface 62N1, the high-k dielectric layer 53, the first N-type shifter layer 54, the gate layer 63, and the gate capping layer 64.

The second N-type gate stack N12 may be sequentially stacked in the order of the interface layer 52, a second N-type dipole interface 62N2, the high-k dielectric layer 53, the first N-type shifter layer 54, the second N-type shifter layer 56, the gate layer 63, and the gate capping layer 64.

The third N-type gate stack N13 may be sequentially stacked in the order of the interface layer 52, a third N-type dipole interface 62N3, the high-k dielectric layer 53, the first N-type shifter layer 54, the second N-type shifter layer 56, the second P-type shifter layer 57, the gate layer 63, and the gate capping layer 64.

The first P-type gate stack P11 may be sequentially stacked in the order of the interface layer 52, a first P-type dipole interface 62P1, the high-k dielectric layer 53, the first P-type shifter layer 55, the gate layer 63, and the gate capping layer 64.

The second P-type gate stack P12 may be sequentially stacked in the order of the interface layer 52, a second P-type dipole interface 62P2, the high-k dielectric layer 53, the first P-type shifter layer 55, the second N-type shifter layer 56, the gate layer 63, and the gate capping layer 64.

The third P-type gate stack P13 may be sequentially stacked in the order of the interface layer 52, a third P-type dipole interface 62P3, the high-k dielectric layer 53, the first P-type shifter layer 55, the second N-type shifter layer 56, the second P-type shifter layer 57, the gate layer 63, and the gate capping layer 64.

In accordance with FIGS. 21 and 31, various processes known to a person of ordinary skill in the art may be performed following a gate patterning process.

Threshold voltages of the N-channel transistors in the N-channel transistor region NR may vary depending on the content, i.e., type and/or concentration of dipole inducing chemical species contained in the first to third N-type dipole interfaces 62N1 to 62N3. Threshold voltages of the P-channel transistors in the P-channel transistor region PR may vary depending on the content, i.e., type and/or concentration of dipole inducing chemical species contained in the first to third P-type dipole interfaces 62P1 to 62P3. For example, the lowest threshold voltage may be achieved based on a high concentration of diffused dipole inducing chemical species and the highest threshold voltage may be achieved based on a low concentration of diffused dipole inducing chemical species.

Among the first to third N-type gate stacks N11 to N13, the second N-type dipole interface 62N2 of the second N-type gate stack N12 may have the highest concentration of dipole inducing chemical species, and the third N-type dipole interface 62N3 of the third N-type gate stack N13 may have the lowest concentration of dipole inducing chemical species. Thus, the third N-type gate stack N13 may induce the highest threshold voltage and the second N-type gate stack N12 may induce the lowest threshold voltage. The threshold voltage induced by the first N-type gate stack N11 may be higher than the threshold voltage induced by the second N-type gate stack N12 and lower than the threshold voltage induced by the third N-type gate stack N13. The threshold voltage induced by the third N-type gate stack N13 is highest because the third N-type dipole interface 62N3 has the lowest concentration of dipole inducing chemical species which may be caused by an interference effect between the first and second N-type shifter layers 54 and 56 and the second P-type shifter layer 57. In other words, an interference between an N-type dipole inducing material and a P-type dipole inducing material may suppress a diffusion of dipole inducing materials.

Among the first to third P-type gate stacks P11 to P13, the first P-type dipole interface 62P1 of the first P-type gate stack P11 may include the highest concentration of dipole inducing chemical species, and the second P-type dipole interface 62P2 of the second P-type gate stack P12 may have the lowest concentration of dipole inducing chemical species. Thus, the second P-type gate stack P12 may induce the highest threshold voltage and the first P-type gate stack P11 may induce the lowest threshold voltage. The threshold voltage induced by the third P-type gate stack P13 may be higher than the threshold voltage induced by the first P-type gate stack P11 and lower than the threshold voltage induced by the second P-type gate stack P12. The threshold voltage induced by the second P-type gate stack P12 may be highest because of an interference effect between the second N-type shifter layer 56 and the first P-type shifter layer 55. In other words, an interference between an N-type dipole inducing material and a P-type dipole inducing material may suppress a diffusion of dipole inducing materials.

In accordance with embodiments of the present invention, direct or indirect damages, caused by a cleaning or an ashing process, on the first N-type shifter layer 54, the first P-type shifter layer 55, and the high-k dielectric layer 53 may be fundamentally prevented through a series of processes that sequentially remove shifter layers from the top.

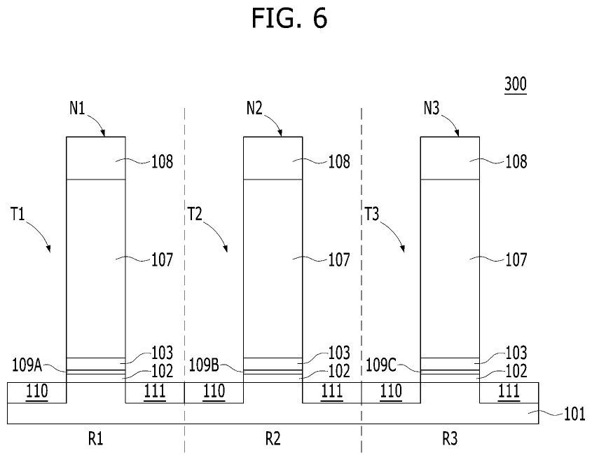

FIG. 6 is a diagram illustrating a semiconductor device according to an embodiment of the present disclosure.

Referring to FIG. 6, a semiconductor device 300 may include a first transistor T1, a second transistor T2, and a third transistor T3. The first transistor T1 may be formed over a first region R1, the second transistor T2 may be formed over a second region R2, and the third transistor T3 may be formed over a third region R3. Each of the first to third transistors T1 to T3 may be NMOSFET. Although not illustrated, the first to third transistors T1 to T3 may be divided by an isolation layer as is well-known in the art. In this regard, it is noted that well known features may be omitted for avoiding obfuscating the description with unnecessary details of well-known features.

The first transistor T1 may include a first gate stack N1 formed over a substrate 101 in the first region R1. The first transistor T1 may include a first source region 110 and a first drain region 111 formed on both sides of the first gate stack Ni over the substrate 101. The first gate stack N1 may be formed to include an interface layer 102, a high-k dielectric layer 103, a gate electrode 107, and a gate capping layer 108 which are sequentially stacked in the recited order. The first gate stack N1 may further include a first dipole interface 109A formed between the interface layer 102 and the high-k dielectric layer 103. The first dipole interface 109A may include dipole inducing chemical species for controlling a threshold voltage of the first transistor T1. The threshold voltage of the first transistor T1 is controlled by the first dipole interface 109A. In an embodiment, the first dipole interface 109A may include lanthanides. The first dipole interface 109A may include, for example, lanthanum (La).

The second transistor T2 may include a second gate stack N2 formed over the substrate 101 in the second region R2. The second transistor T2 may include the first source region 110 and the first drain region 111 formed on both sides of the second gate stack N2 over the substrate 101. The second gate stack N2 may be formed to include the interface layer 102, the high-k dielectric layer 103, the gate electrode 107, and the gate capping layer 108 which are sequentially stacked in the recited order. The second gate stack N2 may further include a second dipole interface 109B formed between the interface layer 102 and the high-k dielectric layer 103. The second dipole interface 109B may include dipole inducing chemical species for controlling a threshold voltage of the second transistor T2. The threshold voltage of the second transistor T2 is controlled by the second dipole interface 109B. In an embodiment, the second dipole interface 109B may include lanthanides. The second dipole interface 109B may include, for example, lanthanum (La).

The third transistor T3 may include a third gate stack N3 formed over the substrate 101 in the third region R3. The third transistor T3 may include the first source region 110 and the first drain region 111 formed on both sides of the third gate stack N3 over the substrate 101. The third gate stack N3 may be formed to include the interface layer 102, the high-k dielectric layer 103, the gate electrode 107, and the gate capping layer 108 which are sequentially stacked in the recited order. The third gate stack N3 may further include a third dipole interface 109C formed between the interface layer 102 and the high-k dielectric layer 103. The third dipole interface 109C may include dipole inducing chemical species for controlling a threshold voltage of the third transistor T3. The threshold voltage of the third transistor T3 is controlled by the third dipole interface 109C. The third dipole interface 109C may include lanthanides. The third dipole interface 109C may include, for example, lanthanum (La).

In accordance with FIG. 6, the first to third transistors T1 to T3 may have different threshold voltages. For example, the first transistor T1 formed in the first region R1 may have a lower threshold voltage than the second transistor T2 formed in the second region R2 and the third transistor T3 formed in the third region R3. The second transistor T2 formed in the second region R2 may have a lower threshold voltage than the third transistor T3 formed in the third region R3. The threshold voltages of the first to third transistors T1 to T3 may be determined respectively by the first, second, and third dipole interfaces 109A, 109B, and 109C.

A threshold voltage may differ depending on the content, i.e., type and/or concentration of dipole inducing chemical species contained in the first to third dipole interfaces 109A to 109C. For example, the lowest threshold voltage may be achieved based on a high concentration of diffused dipole inducing chemical species and the highest threshold voltage may be achieved based on a low concentration of diffused dipole inducing chemical species. The second dipole interface 109B of the second transistor T2 may have the highest concentration of dipole inducing chemical species and the third dipole interface 109C of the third transistor T3 may have the lowest concentration of dipole inducing chemical species. Thus, the threshold voltage of the third transistor T3 may be highest and the threshold voltage of the second transistor T2 may be lowest.

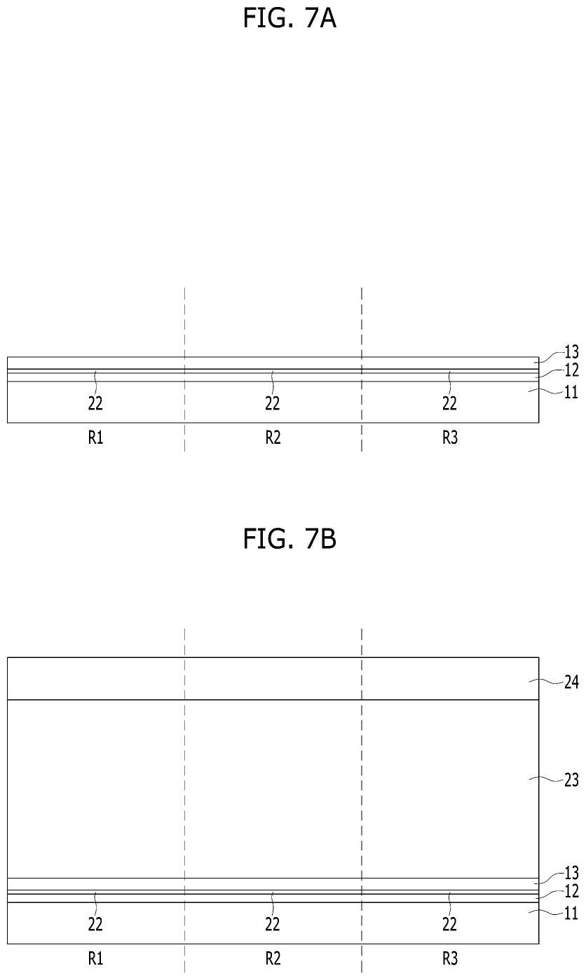

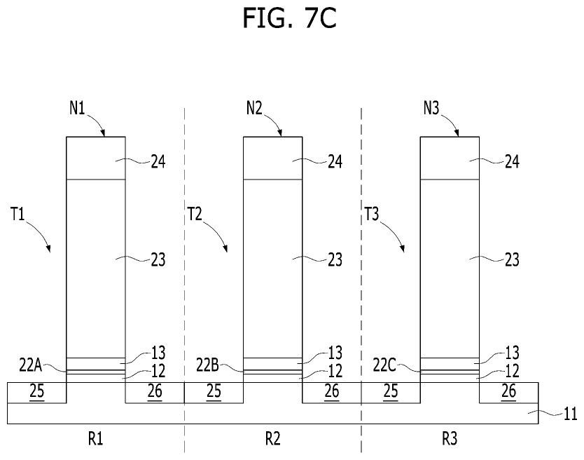

FIGS. 7A to 7C are diagrams illustrating another method for fabricating a semiconductor device according to an embodiment of the present disclosure.

The dipole interface 22 may be formed between the high-k dielectric layer 13 and the interface layer 12 by the method illustrated in FIGS. 2A to 2F. The dipole interface 22 may be formed by the post thermal treatment 21 illustrated in FIG. 2F. In accordance with FIG. 2F, first, second, and third diffusions D1, D2, D3 of dipole inducing is materials from the first to third shifter layers 14 to 16 may result from the post thermal treatment 21. Diffused dipole inducing materials may be disposed between the high-k dielectric layer 13 and the interface layer 12. The second diffusion D2 may include the largest diffusion concentration of dipole inducing materials and the third diffusion D3 may include the smallest diffusion concentration of dipole inducing materials. A diffusion concentration of the first diffusion D1 may be smaller than the second diffusion D2 and larger than the third diffusion D3. A difference in a concentration of the diffusions may be determined by a different stack composition of the first to third shifter layers 14 to 16. The dipole interface 22 may be formed in each of the first to third regions R1 to R3. Each of the first to third shifter structures SF1 to SF3 may include the dipole interface 22.

Subsequently, as illustrated in FIG. 7A, the first shifter layer 14, the second shifter layer 15, and the third shifter layer 16 may be removed.

In accordance with FIG. 7B, a gate layer 23 may be formed over the high-k dielectric layer 13. The gate layer 23 may be formed of any suitable material including, for example, polysilicon, metal, metal nitride, or combinations thereof. For example, in an embodiment, the gate layer 23 may be sequentially stacked in the order of polysilicon, titanium oxide, and tungsten. In accordance with another embodiment of the present invention, the gate layer 23 may be sequentially stacked in the order of titanium nitride, tungsten, and polysilicon.

A gate capping layer 24 may be formed over the gate layer 23. The gate capping layer 24 may be formed of any suitable material including, for example, silicon nitride.

In accordance with FIG. 7C, a gate patterning process may be performed. Although not illustrated, a gate mask may be used to sequentially etch the gate capping layer 24, the gate layer 23, the high-k dielectric layer 13, and the interface layer 12. Accordingly, the first gate stack N1 may be formed over the first region R1 of the substrate 11, the second gate stack N2 may be formed over the second region R2 of the substrate 11, and the third gate stack N3 may be formed over the third region R3 of the substrate 11.

The first gate stack N1 may be sequentially stacked in the order of the interface layer 12, a first dipole interface 22A, the high-k dielectric layer 13, the gate layer 23, and the gate capping layer 24.

The second gate stack N2 may be sequentially stacked in the order of the interface layer 12, a second dipole interface 22B, the high-k dielectric layer 13, the gate layer 23, and the gate capping layer 24.

The third gate stack N3 may be sequentially stacked in the order of the interface layer 12, a third dipole interface 22C, the high-k dielectric layer 13, the gate layer 23, and the gate capping layer 24. The interface layer 12, the high-k dielectric layer 13, the gate layer 23, and the gate capping layer 24 may be made of a same material in the first to third gate stacks N1 to N3.

The first to third dipole interfaces 22A, 22B, and 22C may include dipole inducing chemical species in different concentrations.

A source/drain 25/26 formation process may be performed. The source/drain 25/26 may be formed in each of the first to third regions R1 to R3. The source/drain 25/26 may include an N-type dopant. As described above, the first to third transistors T1 to T3 may be formed by forming the source/drain 25/26.

The first transistor T1 may include the first gate stack N1 and the source/drain 25/26. The second transistor T2 may include the second gate stack N2 and the source/drain 25/26. The third transistor T3 may include the third gate stack N3 and the source/drain 25/26.

The first to third transistors T1 to T3 may be N-channel transistors including NMOSFET type transistors.

The first to third transistors T1 to T3 may have different threshold voltages. For example, the first transistor T1 formed in the first region R1 may have a threshold voltage lower than third transistors T3 formed in the third regions R3. The second transistor T2 formed in the second region R2 may have a threshold voltage lower than the first transistor T1 formed in the first region R1. The second transistor T2 formed in the second region R2 may have a threshold voltage lower than the third transistor T3 formed in the third region R3. Different threshold voltages of the first to third transistors T1 to T3 may be respectively determined by the first to third dipole interfaces 22A to 22C.

The threshold voltage may vary depending on the content, i.e., the type and/or concentration of dipole inducing chemical species contained in the first to third dipole interfaces 22A to 22C. For example, the lowest threshold voltage may be achieved based on a high concentration of diffused dipole inducing chemical species and the highest threshold voltage may be achieved based on a low concentration of diffused dipole inducing chemical species. The second dipole interface 22B of the second transistor T2 may have the highest concentration of dipole inducing chemical species, and the third dipole interface 22C of the third transistor T3 may have the lowest concentration of dipole inducing chemical species. The concentration of dipole inducing chemical species in the first dipole interface 22A may be smaller than the concentration in the second dipole interface 22B and larger than the concentration in the third dipole interface 22C. Thus, the third transistor T3 may have the highest threshold voltage and the second transistor T2 may have the lowest threshold voltage. The first transistor T1 may have a threshold voltage higher than the second transistor T2 and lower than the third transistor T3.

Although the embodiments of the present invention illustrate methods for fabricating a complementary metal-oxide-semiconductor field-effect-transistor (CMOSFET), the present invention is not limited thereto. The present disclosure can be applied to any method for fabricating a semiconductor device where a N-channel transistor and a P-channel transistor are formed. For example, the present disclosure may be applied to a memory device such as dynamic random access memory (DRAM), ferroelectric random access memory (FeRAM), 3-dimension NAND (3D NAND), phase change random access memory (PCRAM), spin-transfer torque random access memory (STT RAM), and so forth. Also, the present disclosure may be applied to CMOSFET of a peripheral circuit which requires a high-speed operation of CIS (CMOS Image Sensor).

The above-described invention is not limited by the embodiments described or figures included herein. In view of the present disclosure, other additions, subtractions, or modifications are apparent to a person of ordinary skill in the art and are intended to fall within the scope of the appended claims.

What is claimed is:

1. A semiconductor device, comprising:
a substrate including a first NMOS region and a second NMOS region;
a first transistor including a first shifter layer disposed in the first NMOS region; and
a second transistor including a second shifter layer disposed in the second NMOS region,
wherein each of the first shifter layer and the second shifter layer includes first dipole inducing species and the second shifter layer further includes second dipole inducing species.

2. The semiconductor device of claim 1, wherein the first dipole inducing species are different from the second dipole inducing species.

3. The semiconductor device of claim 1,
wherein the first shifter layer is formed of an N-type dipole inducing material, and
wherein the second shifter layer is formed of a combination of an N-type dipole inducing material and a P-type dipole inducing material.

4. The semiconductor device of claim 1, wherein the first shifter layer includes one or more layers of an N-type dipole inducing material.

5. The semiconductor device of claim 1, wherein the second shifter layer includes a stack of double layers of an N-type dipole inducing material and a single layer of a P-type dipole inducing material.

6. The semiconductor device of claim 1, wherein a threshold voltage of the first transistor is lower than a threshold voltage of the second transistor.

7. The semiconductor device of claim 1,
wherein the first transistor further includes:
a first interface layer disposed between the first shifter layer and the substrate;
a first high-k dielectric layer over the first interface layer; and
a first dipole interface disposed between the first interface layer and the first high-k dielectric layer, and
wherein the first dipole interface includes the first dipole inducing species diffused from the first shifter layer.

8. The semiconductor device of claim 1,
wherein the second transistor further includes:
a second interface layer disposed between the second shifter layer and the substrate;
a second high-k dielectric layer over the second interface layer; and
a second dipole interface disposed between the second interface layer and the second high-k dielectric layer, and
wherein the second dipole interface includes the first dipole inducing species diffused from the second shifter layer.

9. The semiconductor device of claim 1,
wherein the first transistor further comprises a first dipole interface disposed between the first shifter layer and the substrate, and the first dipole interface includes the first dipole inducing species diffused from the first shifter layer, and
wherein the second transistor further comprises a second dipole interface disposed between the second shifter layer and the substrate, and the second dipole interface includes the first dipole inducing species diffused from the second shifter layer.

10. The semiconductor device of claim 9,
wherein the first dipole interface has a higher concentration of the first dipole inducing species than the second dipole interface.

11. The semiconductor device of claim 1, wherein each of the first shifter layer and the second shifter layer includes a lanthanum atom.

12. The semiconductor device of claim 1,
wherein the first shifter layer includes lanthanum oxide, and
wherein the second shifter layer includes a combination of lanthanum oxide and aluminum oxide.

13. A semiconductor device, comprising:
a substrate including a first PMOS region and a second PMOS region;
a first transistor including a first shifter layer disposed in the first PMOS region; and
a second transistor including a second shifter layer disposed in the second PMOS region,
wherein the first shifter layer includes a P-type dipole inducing material and the second shifter layer includes a combination of a P-type dipole inducing material and an N-type dipole inducing material.

14. The semiconductor device of claim 13, wherein the first shifter layer includes one or more layers of the P-type dipole inducing material.

15. The semiconductor device of claim 13, wherein the second shifter layer includes a stack of a single layer of the N-type dipole inducing material and a single layer of the P-type dipole inducing material.

16. The semiconductor device of claim 13, wherein the second shifter layer includes a plurality of the P-type dipole inducing materials and a single layer of the N-type dipole inducing material between the P-type dipole inducing materials.

17. The semiconductor device of claim 13, wherein a threshold voltage of the first transistor is lower than a threshold voltage of the second transistor.

18. The semiconductor device of claim 13,
wherein the first transistor further includes:
a first interface layer between the first shifter layer and the substrate;
a first high-k dielectric layer over the first interface layer; and
a first dipole interface disposed between the first interface layer and the first high-k dielectric layer, and
wherein the first dipole interface includes the P-type dipole inducing materials diffused from the first shifter layer.

19. The semiconductor device of claim 13,
wherein the second transistor includes:
a second interface layer between the second shifter layer and the substrate;
a second high-k dielectric layer over the second interface layer; and
a second dipole interface disposed between the second interface layer and the second high-k dielectric layer, and
wherein the second dipole interface includes the P-type dipole inducing materials diffused from the second shifter layer.

20. The semiconductor device of claim 13,
wherein the first transistor further comprises a first dipole interface disposed between the first shifter layer and the substrate, and the first dipole interface includes the P-type dipole inducing species diffused from the first shifter layer, and
wherein the second transistor further comprises a second dipole interface disposed between the second shifter layer and the substrate, and the second dipole interface includes the P-type dipole inducing species diffused from the second shifter layer.

21. The semiconductor device of claim 20,
wherein the first dipole interface has a higher concentration of the P-type dipole inducing species than the second dipole interface.

22. The semiconductor device of claim 13, wherein each of the first shifter layer and the second shifter layer includes an aluminum atom.

23. The semiconductor device of claim 13,
wherein the first shifter layer includes aluminum oxide, and
wherein the second shifter layer includes a combination of lanthanum oxide and aluminum oxide.

24. A method for fabricating a semiconductor device, the method comprising:
sequentially stacking an interface layer and a high-k dielectric layer on a substrate, in which a NMOS region and a PMOS region are defined;
forming a first N-type shifter layer over the high-k dielectric layer in the NMOS region;
forming a first P-type shifter layer over the high-k dielectric layer in the PMOS region;
forming a second N-type shifter layer over the first N-type shifter layer and the first P-type shifter layer;
forming a second P-type shifter layer over the second N-type shifter layer;
sequentially patterning the second P-type shifter layer, the second N-type shifter layer, and the first N-type shifter layer to form a plurality of N-type shifter structures over the NMOS region of the substrate; and
sequentially patterning the second P-type shifter layer, the second N-type shifter layer, and the first P-type shifter layer to form a plurality of P-type shifter structures over the PMOS region of the substrate.

25. The method according to claim 24, wherein the first and second N-type shifter layer includes N-type dipole inducing species, and the first and second P-type shifter layer includes P-type dipole inducing species.

26. The method according to claim 25, further comprising, after the N-type shifter structures and the P-type shifter structures are formed,
performing a post thermal treatment to form a plurality of dipole interfaces between the interface layer and the high-k dielectric layer; and
forming gate electrodes on the N-type and P-type shifter structures, respectively.

27. The method according to claim 26, wherein the dipole interfaces comprising:
a plurality of N-type dipole interfaces with the N-type dipole inducing species diffused from the N-type shifter structure; and
a plurality of P-type dipole interfaces with the P-type dipole inducing species diffused from the P-type shifter structures.

28. The method according to claim 27, wherein the N-type dipole interfaces have different concentrations of the N-type dipole inducing species, and the P-type dipole interfaces have different concentrations of the P-type dipole inducing species.

29. The method according to claim 24, wherein each of the first N-type shifter layer and the second N-type shifter layer includes lanthanum oxide.

30. The method according to claim 24, wherein each of the first P-type shifter layer and the second P-type shifter layer includes aluminum oxide.
